(19) United States
(12) Patent Application Publication
(10) Pub. No.: US 2017/0126131 A1
(43) Pub. Date: May 4, 2017

(54) DUAL LOW-VOLTAGE GATE DRIVERS FOR BATTERY-POWERED APPLICATIONS

(71) Applicant: TF Semiconductor Solutions, Inc., Torrance, CA (US)

(72) Inventor: Jong Deog Jeong, Torrance, CA (US)

(73) Assignee: TF Semiconductor Solutions, Inc., Torrance, CA (US)

(21) Appl. No.: 15/339,918

(22) Filed: Oct. 31, 2016

Related U.S. Application Data
(60) Provisional application No. 62/249,168, filed on Oct. 30, 2015.

(51) Int. Cl. H02M 3/158; H03K 17/687; H02J 7/00

(52) U.S. Cl. CPC H02M 3/1582; H02J 7/0065; H03K 17/687; H02J 2007/0067

(57) ABSTRACT

The dual low-voltage driver circuit of the present invention operates as a buck-boost converter. If battery voltage is low (i.e., corresponding to a partially discharged battery), then “buck” section of the circuit is disabled and the “boost” section operates to increase the output voltage to a desired value. On the other hand, if the battery voltage is high (i.e., corresponding to a battery having a fresh charge), then the “boost” circuit is disabled and the “buck” section operates to reduce the output voltage to the desired value.

### FIELD OF THE INVENTION

The present invention relates, generally, to field-effect transistor (FET) gate drivers and, more specifically, to FET gate drivers used for battery-powered applications.

### BACKGROUND OF THE INVENTION

In order to extend operating time of certain applications powered by a lithium battery pack, drivers for field-effect transistors (FETs) must be able to operate at voltages as low as 2.5 VDC.

One example of such an application, where gate drivers must operate at low, direct-current voltages is electronic cigarettes (more commonly known as e-cigarettes). Electronic cigarettes are, essentially, drug delivery devices. A carrier fluid mixed with a drug, such as nicotine, is contained within a vaporization chamber. A battery-powered heating coil module is installed within the vaporization chamber. A hollow mouthpiece is connected to the vaporization chamber. When a user desires the infusion of a dose of the drug into the bloodstream, connection of the battery to the heating coil is made, a quantity of the carrier fluid containing the drug is vaporized, and the user inhales the vaporized fluid into his lungs. The drug is rapidly absorbed into the bloodstream and travels to the brain, thereby bringing temporary relief from the body's craving for the drug. The process can be repeated whenever the cravings for the drug return. For efficient operation of electronic cigarettes, it is desirable to apply constant voltage to the heating coil so that uniform dosages of vapor are maintained.

Battery-powered manned or unmanned aircraft are another application where gate drivers operating at low voltages are used to control power delivery to electric motors.

In both of these applications, low voltage operation is essential in order to increase operating time as battery voltage decreases as the battery charge is depleted over time.

### SUMMARY OF THE INVENTION

The primary objective of the present invention is to provide a driver circuit that delivers a constant voltage at the circuit's output terminal. The dual low-voltage driver circuit operates as a buck-boost converter. If battery voltage is low (i.e., corresponding to a partially discharged battery), then “buck” section of the circuit is disabled and the “boost” section operates to increase the output voltage to the desired value. On the other hand, if the battery voltage is high (i.e., corresponding to a battery having a fresh charge), then the “boost” circuit is disabled and the “buck” section operates to reduce the output voltage to the desired value.

### BRIEF DESCRIPTION OF THE DRAWINGS

FIG. 1 is a block circuit diagram of a dual low-voltage gate driver circuit without integrated MOSFETs; and

FIG. 2 is a block circuit diagram of a dual low-voltage gate driver circuit having integrated MOSFETs.

### PREFERRED EMBODIMENT OF THE INVENTION

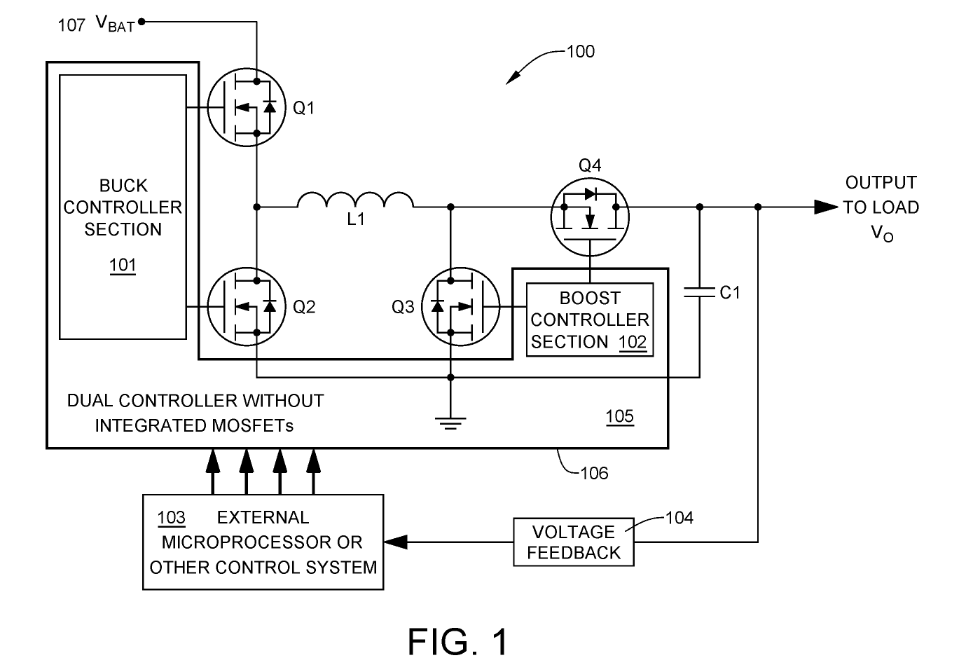

The invention will be described with reference to the attached drawing figures. Referring now to FIG. 1, a first embodiment of the new driver circuit 100 comprises a first gate driver module identified as the Buck Controller Section 101, a second gate driver module identified as the Boost Controller Section 102, an external control module 103 incorporating a microcontroller, or a microprocessor and associated support circuitry, or equivalent control circuitry, MOSFETs Q1 and Q2, which are associated with the Buck Controller Section 101, and MOSFETs Q3 and Q4, which are associated with the Boost Controller Section 102. An inductor L1, a capacitor C1, and a voltage feedback line 104 between the circuit output V_{O} and the external control module 103, are discrete components that are not a part of the integrated circuit portion 105 of the driver circuit 100, which is enclosed within the area surrounded by the heavy solid line 106. For this first embodiment of the driver circuit 100, MOSFETs Q1, Q2, Q3 and Q4 are also discrete components, which are not part of the integrated circuit portion 105 of the driver circuit 100. A battery (V_{BAT}) 107, though not part of the dual low-voltage driver circuit, provides power to the driver circuit 100 and to the output V_{O}, which powers the load.

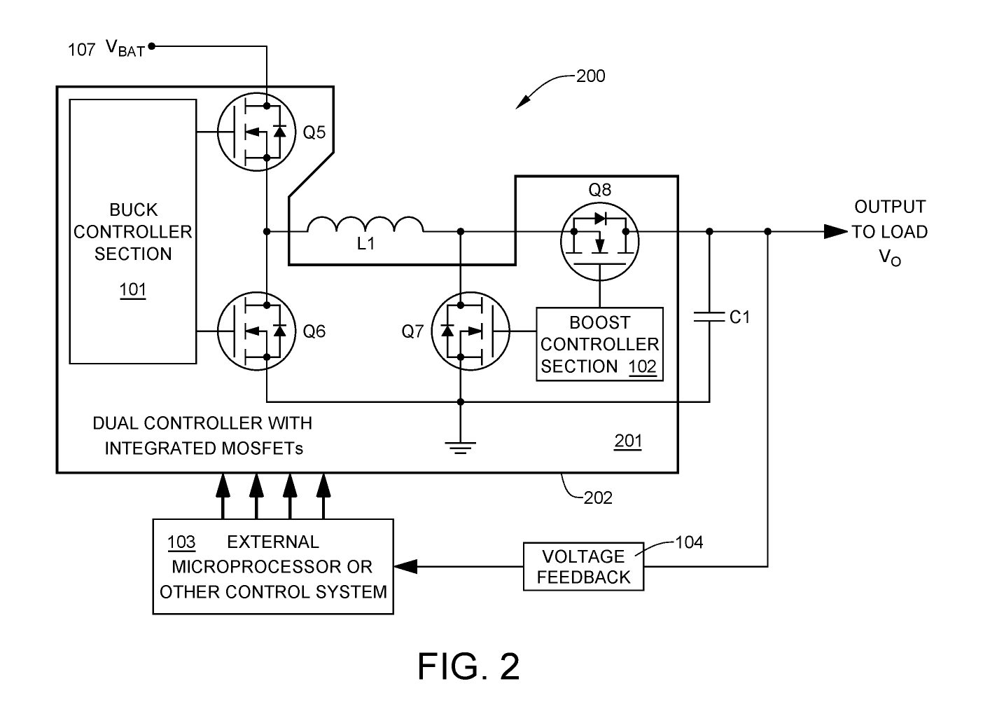

Referring now to FIG. 2, a second embodiment of the new driver circuit 200 differs from the first embodiment of FIG. 1 in that MOSFETs Q1, Q2, Q3 and Q4 of driver circuit 100 have been incorporated in the integrated circuit portion 201 of driver circuit 200. The portion of circuit 200 that has been fabricated as an integrated circuit on a single chip, with MOSFETs Q1, Q2, Q3 and Q4 renamed Q5, Q6, Q7 and Q8, respectively, is enclosed by a solid line 202. The item numbers of the battery 107 and of the output V_{O} have not been changed in FIG. 2.

Referring once again to FIG. 1, the first embodiment dual low-voltage driver circuit 100 operates as a buck-boost converter. If battery voltage V_{BAT} 107 is low (i.e., corresponding to the battery being partially discharged), then the Buck Controller Section 101 is disabled, with MOSFET Q1 being constant ON and MOSFET Q2 being constant OFF, and the Boost Controller Section 102 operating MOSFETs Q3 and Q4 in a pulsed mode so as to increase the output voltage V_{O} to the desired value. When MOSFET Q3 is ON, MOSFET Q4 is OFF, and visa versa. When MOSFET Q4 is ON, the current path is from the battery 107, through inductor L1, through MOSFET Q4, and to the load V_{O}. The voltage on capacitor C1 is pumped up by the continual collapsing of the magnetic field on inductor L1. This continues until the voltage feedback 104 senses an adequate charge on capacitor C1. On the other hand, if the battery voltage V_{BAT} is high (i.e., corresponding to the battery 107 having a fresh charge), then the Boost Controller Section 102 is disabled, with MOSFET Q3 being constant OFF and MOSFET 4 being constant ON, and the Buck Controller Section 101 operating MOSFETs Q1 and Q2 in a pulsed mode so as to reduce the output voltage V_{O} to the desired value. By pulsing the current from battery 107, charge on capacitor C1 is maintained at a lower-than-battery-voltage level. Only when the battery 107 is optimally charged are both the Buck Controller Section 101 and the Boost Controller Section 102 non operational. With MOSFETS Q2 and Q3 both OFF, currently flows directly from the battery 107, through MOSFET Q1, through inductor L1, and through MOSFET Q4 to the load V_{O}. The external control module 103 receives voltage level feedback via a voltage feedback 104 line that is coupled to the output V_{O}. The external control module 103 is responsible for controlling the Buck Controller Section 101 and the Boost Controller Section 102 so that the desired output voltage V_{O} is maintained. At some point, the battery voltage will drop to a level that is so low that the Boost Controller Section 102 will no longer be able to adequately boost the voltage to the desired output voltage V_{O}.

Referring once again to FIG. 2, with the exception that MOSFETS Q1, Q2, Q3 and Q4 are integrated into the integrated circuit portion 201 of driver circuit 200, the second embodiment dual low-voltage driver circuit 200 operates identically to the first embodiment dual low-voltage driver circuit 100. MOSFETS Q5, Q6, Q7, and Q8 operate in the same manner as MOSFETS Q1, Q2, Q3 and Q4 of FIG. 1, respectively.

For the same of nomenclature, the Buck Controller Section 101 is one low-voltage gate driver, and the Boost Controller Section 102 is the other low-voltage gate driver.

Although only two embodiments of a dual low-voltage gate driver circuit for battery-powered applications have been shown and described, it will be obvious to those having ordinary skill in the art that changes and modifications may be made thereto without departing from the scope and the spirit of the invention as hereinafter claimed.

What is claimed is:

1. A dual low-voltage driver circuit comprising:
a buck controller section which independently controls first and second MOSFETS, said first MOSFET receiving a voltage input from a battery; and
a boost controller section, which independently controls third and fourth MOSFETS, said fourth MOSFET providing a voltage output to a load;
wherein, with said buck controller section disabled, said boost controller section operates to increase voltage output when battery voltage falls below an optimum range; and
wherein, with said boost controller section disabled, said buck controller section operates to decrease voltage output when battery voltage is above an optimum range; and
wherein both said buck controller section and said boost controller section are disabled while battery voltage in in an optimum range.

2. The dual low-voltage driver circuit of claim 1, wherein voltage output is increased by alternately switching third and fourth MOSFETS ON and OFF, thereby repeatedly generating and collapsing a magnetic field in a conductor, which when transferred to the voltage output, charges a capacitor.

3. The dual low-voltage driver circuit of claim 1, wherein voltage output is decreased by alternately switching first and second MOSFETS ON and OFF, thereby causing a node between them to drop below the battery voltage to the optimum range.
